(19) United States
(12) Patent Application Publication
(10) Pub. No.: US 2024/0241996 A1
(43) Pub. Date: Jul. 18, 2024

(54) BIM VISUALIZATION SYSTEMS AND APPARATUSES, VISUALIZATION PLATFORMS, AND STORAGE MEDIA

(71) Applicant: BOE Technology Group Co., Ltd., Beijing (CN)

(72) Inventor: Danfeng ZHU, Beijing (CN)

(21) Appl. No.: 17/915,724

(22) PCT Filed: Sep. 30, 2021
(86) PCT No.: PCT/CN2021/122097

§ 371 Date: Sep. 29, 2022

(51) Int. Cl. G06F 30/12; G06Q 50/08

(52) U.S. Cl. CPC G06F 30/12; G06Q 50/08

(57) ABSTRACT

A BIM visualization system and apparatus, a visualization platform, and a storage medium are provided. The system includes: a visualization platform and a management platform. The management platform comprises a design client and a construction client. The management platform is configured to acquire design data uploaded by the design client and construction data uploaded by the construction client, and is further configured to forward the design data to the construction client. The visualization platform is configured to acquire the design data and the construction data from the management platform, generate a three-dimensional model according to the design data and the construction data, and display the three-dimensional model.

### TECHNICAL FIELD

The present disclosure relates to the field of data processing technology, and in particular, to BIM visualization systems and apparatuses, visualization platforms, and storage media.

### BACKGROUND

BIM (Building Information Modeling) technology is a data tool applied to engineering design, construction, and management, and data and information models of buildings can be shared and transmitted during a full life cycle including project planning, running and maintenance through integration of the data and information models, so that various building information can be correctly understood and efficiently responded to. Therefore, BIM can provide a basis for collaborative work for design teams and construction entities of various parties including building and operation units, and play an important role in improving production efficiency, saving costs, and shortening construction periods.

In practical applications, because building industry includes multiple branches, and there are many design layers, construction layers and supervision layers who use data in different ways, the flow of data information is incomplete and not timely. For example, impacts of changes in building industry policies on greening rates, assembly rates or other numerical values may cause the construction layers and the design layers to implement schemes using different standards, resulting in needs for rework after completion of a building project, which is easy to cause wastes.

### SUMMARY

The present disclosure provides BIM visualization systems and apparatuses, visualization platforms, and storage media to solve deficiencies in the related art.

According to a first aspect of embodiments of the present disclosure, there is provided a BIM visualization system, including: a visualization platform and a management platform, where the management platform includes a design client and a construction client;
the management platform is configured to acquire design data uploaded by the design client and construction data uploaded by the construction client, and is further configured to forward the design data to the construction client;
the visualization platform is configured to acquire the design data and the construction data from the management platform, generate a three-dimensional model according to the design data and the construction data, and display the three-dimensional model.

Optionally, the management platform further includes a supervision client, and the management platform is further configured to generate supervision data by the supervision client and forward the supervision data to the design client and the construction client.

Optionally, the supervision client is configured to acquire preset design data and the design data forwarded by the management platform, and compare the design data with the preset design data to generate design supervision data.

Optionally, the supervision client is configured to acquire preset product data and product data forwarded by the management platform, and compare the preset product data with the product data to generate production supervision data, where the production supervision data is used to characterize whether products satisfy requirements of the preset product data.

Optionally, the supervision client is configured to acquire the design data and the construction data forwarded by the management platform, and compare the design data with the construction data to generate construction supervision data, where the construction supervision data is used to characterize whether the products are subjected to construction operation according to the requirements of the preset product data.

Optionally, the management platform is configured to compare the design data with product data forwarded by the management platform to generate first comparison data, where the first comparison data is used to characterize whether products satisfy requirements of the design data.

Optionally, the management platform is configured to compare product data forwarded by the management platform with physical operation data to generate second comparison data, where the second comparison data is used to characterize whether physical products satisfy requirements of the product data.

Optionally, the system further includes: a technique and construction method database, where the technique and construction method database communicates with the management platform; and the management platform is configured to acquire the design data form the technique and construction method database, and forward the design data to the design client, the construction client, or a supervision client in the management platform.

Optionally, the management platform further includes a production client, and the management platform is further configured to acquire preset product data and product data uploaded by the production client.

Optionally, the management platform includes: a cloud database configured to store preset design data and preset product data.

The technical solutions provided by the embodiments of the present disclosure may include the following beneficial effects:

As can be seen from the embodiments, the technical solutions according to the present disclosure provide a BIM visualization system, which may include: a visualization platform and a management platform, where the management platform includes a design client and a construction client; the management platform is configured to acquire design data uploaded by the design client and construction data uploaded by the construction client, and is further configured to forward the design data to the construction client; the visualization platform is configured to acquire the design data and the construction data from the management platform, generate a three-dimensional model according to the design data and the construction data, and display the three-dimensional model. In this way, in this embodiment, by generating the three-dimensional model according to the design data and the construction data and displaying the three-dimensional model, various building projects can be visualized, so as to achieve an effect of real-time supervision. In addition, in the present disclosure, the building project can be simulated by generating the three-dimensional model, so as to learn a full life cycle of the building project, which is beneficial to manage the full life cycle; and the construction progress of the building project can be supervised, so as to achieve an effect that the building project satisfies design requirements.

It should be understood that the above general description and the following detailed description are only exemplary and explanatory and are not restrictive of the present disclosure.

### BRIEF DESCRIPTION OF THE DRAWINGS

The accompanying drawings, which are incorporated in and constitute a part of this specification, illustrate examples consistent with the present disclosure and, together with the description, serve to explain the principles of the disclosure.

FIG. 1 is a block diagram illustrating a BIM visualization system according to an exemplary embodiment.

FIG. 2 is a data flow diagram illustrating a BIM visualization system according to an exemplary embodiment.

FIG. 3 is an overall architecture diagram illustrating a BIM visualization system according to an exemplary embodiment.

FIG. 4 is a data flow diagram illustrating a visualized first target model according to an exemplary embodiment.

FIG. 5 is a schematic diagram illustrating an effect of a visualized first target model according to an exemplary embodiment.

FIG. 6 is a schematic diagram illustrating an effect of a situation in which a first midpoint is located outside a bitmap image according to an exemplary embodiment.

FIG. 7 is a schematic diagram illustrating an effect of a situation in which a second midpoint is located within a bitmap image according to an exemplary embodiment.

FIG. 8 is a schematic diagram illustrating a data logic principle according to an exemplary embodiment.

FIG. 9 is a schematic diagram illustrating an effect of acquiring a spacing distance according to an exemplary embodiment.

FIG. 10 is a schematic diagram illustrating an effect of acquiring to-be-processed pixels according to an exemplary embodiment.

FIG. 11 is a schematic diagram illustrating an effect of a second image, i.e., a slot, according to an exemplary embodiment.

### DETAILED DESCRIPTION OF THE EMBODIMENTS

Examples will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

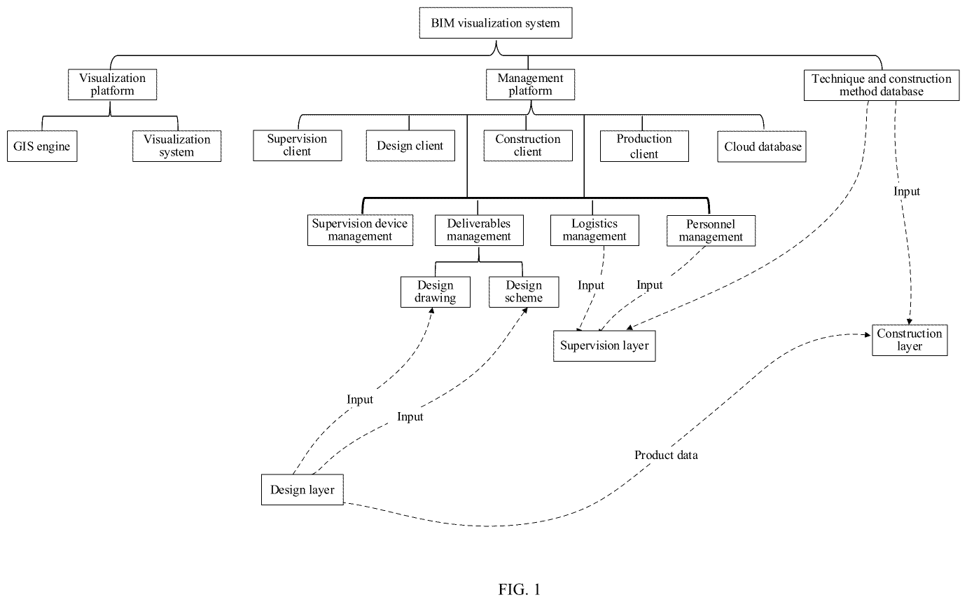

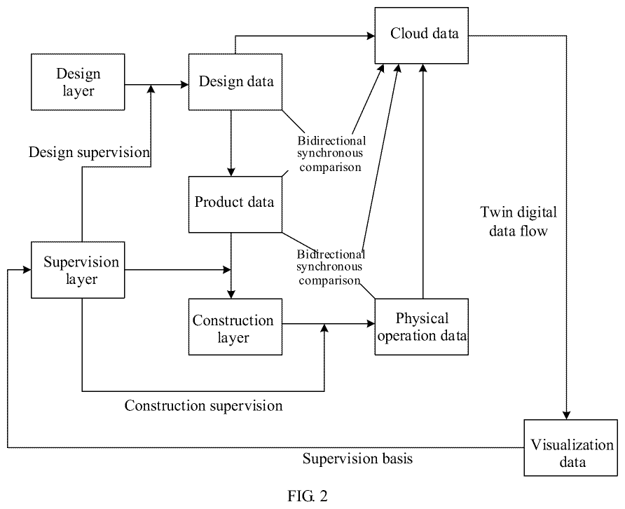

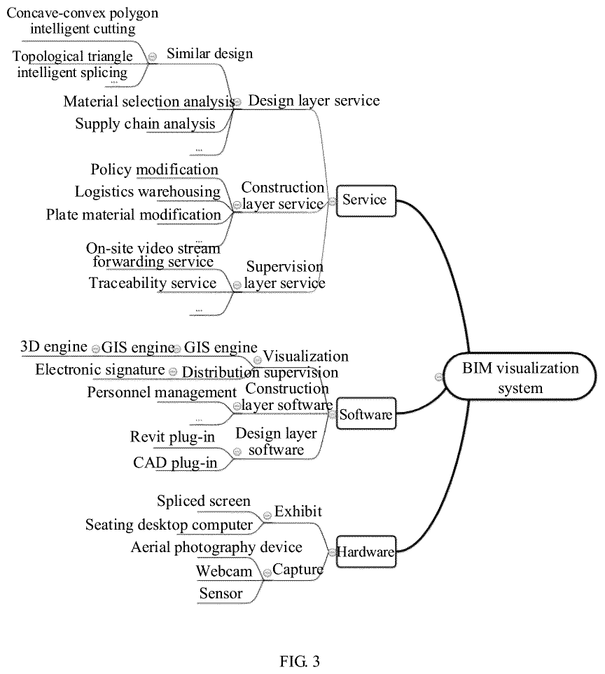

To solve the above technical problems, an embodiment of the present disclosure provides a BIM visualization system. FIG. 1 is a block diagram illustrating a BIM visualization system according to an exemplary embodiment. FIG. 2 is a data flow diagram illustrating a BIM visualization system according to an exemplary embodiment. FIG. 3 is an overall architecture diagram illustrating a BIM visualization system according to an exemplary embodiment. Referring to FIG. 1, FIG. 2 and FIG. 3, a BIM visualization system includes a visualization platform and a management platform. The management platform includes a design client and a construction client.

The management platform is configured to acquire design data uploaded by the design client and construction data uploaded by the construction client, and is further configured to forward the design data to the construction client.

The visualization platform is configured to acquire the design data and the construction data from the management platform, generate a three-dimensional model according to the design data and the construction data, and display the three-dimensional model.

In this embodiment, the visualization platform may be provided with an OSG (OpenSceneGraph) engine. The OSG engine is a cross-platform and open-source interactive graphics program, and can create high-performance graphics for scenes such as air vehicle simulation, games, virtual reality, and visualization in scientific computing. The OSG engine may be deployed with a lightweight engine, and can be deployed on a mobile terminal. In this way, in the embodiments, the design client, the construction client, a production client that will appear subsequently, etc., can be deployed on the mobile terminal, so as to achieve an effect of uploading data in real time. In an example, visualization technology in the visualization platform may be implemented by a GIS engine and a 3D engine in the OSG engine.

In the embodiments, the design client may be connected with existing user design applications (such as AutoDesk) through plug-ins (such as a Revit plug-in and a CAD plug-in), and can perform processing, such as protocol conversion and data format conversion, on design data output by the existing applications. The design client can upload the converted design data to the management platform, and the management platform forwards the converted design data to a technique and construction method database in the BIM visualization system. Alternatively, the design client can communicate with the technique and construction method database through a communication interface of the management platform, and directly upload the design data to the technique and construction method database for storage. In the embodiments, the technique and construction method database is derived from prefabricated buildings in the building industry, and is configured to store design data, construction data, product data, and supervision data uploaded by a supervision client.

The prefabricated buildings refer to buildings fabricated by assembling on sites by preset connection methods structures that are machined and produced in factories (such as floor slabs, wall panels, stairs, and balconies) and then transported to building construction sites, a shift from performing a large number of on-site operations in a traditional construction method. The prefabricated buildings include, but are not limited to, buildings with prefabricated concrete structures, steel structures, modern wood structures, etc. Due to adoption of standardized design, industrialized production, prefabricated construction, informatization management, and intellectualized application, the prefabricated buildings are representatives of modern industrialized production mode and have been more and more widely used.

It should be noted that in the embodiments, users can design a building project, structures used in the building project, preset connection methods of the structures, etc., through the design client to achieve an effect of design standardization, which is convenient for designers to design according to preset design requirements in an early stage of design, and is beneficial to improve design efficiency. In addition, when building industry policies or user requirements are changed, in the embodiments, the users are allowed to update stored preset design data (i.e., design standard or customization requirements) by means of version update or deletion, so as to facilitate the designers to synchronously update design data in time and avoid a problem of inconsistency between the design data and the preset design data, which is beneficial to improve design efficiency.

It should be further noted that, in the embodiments, the following design layer services can be implemented through the design client, including, but not limited to, similar designs (such as concave-convex polygon intelligent cutting and topological triangle intelligent splicing), material selection analysis, supply chain analysis, etc., so as to satisfy requirements of a design layer, which is beneficial to improve design efficiency.

In the embodiments, the management platform includes the production client, and the production client is configured to upload preset product data and product data. The preset product data refers to production layer data determined by a production layer according to the design data, including, but not limited to, raw material types, manufacturers, proportions, production progress data, etc., of structures. The product data refers to actual data acquired by the production layer during actual production of products according to the design data and the preset product data. That is to say, the management platform can further be configured to acquire the preset product data and the product data uploaded by the production client, and forward the preset product data and the product data to the technique and construction method database for storage. Alternatively, the production client can communicate with the technique and construction method database through a communication interface of the management platform, and directly upload the preset product data and the product data to the technique and construction method database for storage.

It should be noted that, in practical applications, production sites are usually provided with corresponding sensors, and the product data can be captured by the sensors provided on the production sites. The sensors may include, but are not limited to, cameras, pressure sensors, temperature sensors, humidity sensors, etc., and the sensors can be disposed according to the production sites and to-be-captured data. The sensors can communicate with the visualization platform deployed with the production client through Bluetooth or WIFI. In this case, the sensors can upload the captured data to the production client through the above communication methods, that is, the production client can acquire the product data.

In the embodiments, the management platform includes the construction client, and the construction client can receive the design data, such as information about design drawings, supply lists, purchase orders, and logistics transportation, evaluate risks and estimate corresponding construction periods, and dismantle a building project according to the design data and the product data to acquire a construction scheme. And the construction client can change the construction scheme according to dynamic states of proportions in actual construction operations, and provide a solution when receiving a supervision instruction. The construction scheme, the changed construction scheme and the solution provided by the construction client can be, as construction data, uploaded to the management platform. In addition, the construction client can use the following services, including, but not limited to, policy modification, logistics warehousing, plate material modification, etc., which is beneficial to improve construction efficiency.

In the embodiments, the management platform includes the supervision client, and the supervision client is configured to generate the supervision data, forward the supervision data to other clients through the management platform, and provide on-site video stream forwarding services, traceability services, etc. The other clients may include at least one of the design client, the production client, or the construction client.

Taking the design layer being supervised as an example, the supervision client can acquire the preset design data from the technique and construction method database and the design data forwarded by the management platform, and then compare the design data with the preset design data to generate design supervision data. In this way, in this example, by supervising the design layer, it is convenient for supervisors to learn design progress and whether the design data matches the preset design data. When the design data matches the preset design data, supervision can be continued, and when the design data does not match the preset design data, a supervision instruction can be generated and sent to the design client to remind the design layer to make corrections in time, so as to achieve an effect of supervision during design and avoid a problem of inconsistency between the design data and the preset design data, which is beneficial to improve supervision efficiency. In addition, when building industry policies or user requirements are changed, the supervision client can supervise whether previous design data is updated synchronously according to the changes, so as to achieve an effect of discovering the inconsistency between the design data and the preset design data in advance, which is beneficial to improve supervision efficiency and can avoid a waste problem caused by subsequent physical reconstruction.

Taking the production layer being supervised as an example, the supervision client can acquire the preset product data from the technique and construction method database and the product data forwarded by the management platform, and then compare the product data with the preset product data to generate production supervision data. In this way, in this example, by supervising the production layer, it is convenient for supervisors to learn production progress and whether the product data matches the preset product data. When the product data matches the preset product data, supervision can be continued, and when the product data does not match the preset product data, a supervision instruction can be generated and sent to the production client to remind the production layer to make corrections in time, so as to achieve an effect of supervision during production and avoid a problem of inconsistency between the product data and the preset product data, which is beneficial to improve supervision efficiency. In addition, when building industry policies or user requirements are changed, the supervision client can supervise whether the preset product data is synchronized, and whether the product data is updated synchronously according to changes in the preset product data, so as to ensure that products satisfy requirements of the preset product data in advance, which is beneficial to improve production quality of the products and improve supervision efficiency.

Taking the construction layer being supervised as an example, the supervision client can acquire the preset product data from the technique and construction method database and the construction data forwarded by the management platform, and then compare the preset product data with the construction data to generate construction supervision data. In this way, in this example, by supervising the construction layer, it is convenient for supervisors to learn construction progress and whether the construction data matches the preset design data. When the construction data matches the preset design data, supervision can be continued, and when the construction data does not match the preset design data, a supervision instruction can be generated and sent to the construction client to remind the production layer to make corrections in time, so as to achieve an effect of supervision during construction and avoid a problem of inconsistency between the construction data and the preset design data, which is beneficial to improve a construction success rate. In addition, when building industry policies or user requirements are changed, the supervision client can supervise whether the construction data is updated synchronously according to the changes, so as to avoid a problem of repeated construction, which is beneficial to improve supervision efficiency.

It should be noted that, in the embodiments, the supervision client can acquire data from different clients and send supervision instructions to the different clients, so that data in supervision layers is uniformly distributed among the layers, which expands the scope of supervision and ensures the quality of building projects. In addition, the BIM visualization system provided in the embodiments can realize remote operations through the supervision client, that is, achieve an effect of remote real-time supervision, which can save human inspection cost.

It should be noted that, in the embodiments, the design client, the production client, the construction client, and the supervision client can be respectively deployed to a visualization platform such as a mobile terminal or a personal computer, and the management platform, as a platform for data forwarding and data processing, can be deployed in a server or a server cluster.

In an embodiment, the management platform can acquire the design data uploaded by the design client and the product data uploaded by the production client, and then compare the design data with the product data to generate first comparison data, where the first comparison data can be used to characterize whether products satisfy requirements of the design data.

In this embodiment, comparing the design data with the product data is a bidirectional synchronous process:

In a first direction, the management platform can send the design data (or production instructions generated according to the design data) to the production layer or the production client (not shown in the drawings), and the production layer can produce structures according to the design data or the production instructions to obtain the product data; then the production layer can upload the product data to the management platform. The management platform can compare the product data with the design data to determine whether the product data matches the design data or satisfies requirements of the design data. The comparison process may include: the management platform processes the design data and the product data into a unified format, and compares the design data with the product data in sequence in the database through a recursive algorithm until all product data is compared to acquire the first comparison data.

In a second direction, the production layer can actively compare to determine whether the produced structures or some of the produced structures satisfy the requirements of the design data during the production, and uploads the comparison result to the management platform. For the comparison process, reference may be made to the comparison process in the first direction, and their difference lies in that the production layer needs to match only data of the produced structures.

It can be understood that the bidirectional synchronous comparison process in this embodiment can be implemented by the management platform or the production layer, and compared with a manual comparison process, can greatly reduce comparison workloads. Besides, objectivity and fairness for the comparison process and the comparison result can be ensured, and data distortion due to human causes can be avoided. In addition, the first comparison data may include data that needs to be processed by the management platform and saved as an archive for use, and may be used for further comparison with the construction supervision data subsequently generated by the supervision client. In an example, the first comparison data can be used directly as production supervision data, that is, the supervision client reads the first comparison data, generates corresponding supervision instructions according to the first comparison data, and sends the supervision instructions to corresponding production client, so as to achieve an effect of reminding the production layer in time.

In an embodiment, the management platform can acquire the product data uploaded by the production client and physical operation data uploaded by the construction client, and then compare the product data with the construction data to generate second comparison data, which can be used to characterize whether physical products satisfy requirements of the product data, such as whether the physical products are previously provided products, or whether data of the physical products captured by sensors matches the product data, that is, based on the second comparison data, it can be determined whether the physical products are replaced, whether the physical products are installed according to preset installation methods, etc.

In this embodiment, comparing the construction data with the product data is a bidirectional synchronous process:

In a first direction, the management platform can send the product data (or construction instructions generated according to the product data) to the construction layer or the construction client. The construction layer can construct according to the product data or the construction instructions to obtain the physical operation data, i.e., the construction data. Then, the construction layer can upload the construction data to the management platform. The management platform can compare the product data and the construction data to determine whether the construction data matches the product data or satisfies requirements of the product data or the design data. The comparison process may include: the management platform processes the construction data and the product data into a unified format, and compares the construction data with the product data in sequence in a database through a recursive algorithm until all construction data is compared to acquire the second comparison data.

In a second direction, the construction layer can actively compare to determine whether the constructed structures or some of the constructed structures satisfy the requirements of the product data during the construction, and uploads the comparison result to the management platform. For the comparison process, reference may be made to the comparison process in the first direction, and their difference lies in that the construction layer needs to match only data of the constructed structures.

It can be understood that the bidirectional synchronous comparison process in this embodiment can be implemented by the management platform or the production layer, and compared with a manual comparison process, can greatly reduce comparison workloads. Besides, objectivity and fairness for the comparison process and the comparison result can be ensured, and data distortion due to human causes can be avoided. In addition, the second comparison data may include data that needs to be processed by the management platform and saved as an archive for use, and may be used for further comparison with the construction supervision data subsequently generated by the supervision client. In an example, the second comparison data can further be used directly as construction supervision data, that is, the supervision client reads the second comparison data, generates corresponding supervision instructions according to the second comparison data, and sends the supervision instructions to corresponding construction client, so as to achieve an effect of reminding the construction layer in time.

In an embodiment, the management platform further includes a cloud database. The cloud database can communicate with the visualization platform, and send the design data and the construction data to the visualization platform. In addition to the design data and the construction data, the cloud database can further be configured to store assembly rates, earthquake resistance levels, sand table data, production material data, etc., at different time periods, and can be set according to actual scenes, which is not limited here.

It should be noted that, in this embodiment, both the cloud database and the technique and construction method database are used to store data. Their differences lie in that: the cloud database is mainly used to store some existing data, which serves as data sources that provide material selection schemes (such as the preset product data) and satisfy rigid indexes such as assembly rates or greening rates, and the cloud database can realize persistent retention and extension of the existing data, which is beneficial to improve productivity of complex building projects, and facilitates subsequent traceability and problem localization. The technique and construction method database is mainly used to store the design data, the product data, basic models of structures (such as walls, beams, plates, and steel bars in the BIM system) or other models, construction equipment models of the production layer, etc., so as to facilitate the visualization platform to quickly read models from the technique and construction method database and generate three-dimensional models. The three-dimensional models can be used as twin data models of physical building projects, which is convenient to manage life cycles of the building projects.

With reference to the differences between the cloud database and the technique and construction method database, the management platform in this embodiment can be configured to acquire the design data from the technique and construction method database, and forward the design data to the design client, the construction client or the supervision client, and the visualization platform can read models from the technique and construction method database and generate three-dimensional models. With reference to map data provided by the GIS engine, the three-dimensional models can be mapped to the map data, which enables multiple building projects to be managed with geographic information, and a visualization model effect can display project progress and corresponding data indexes in real time.

Continuing to refer to FIG. 2, a working process of a BIM visualization system provided by an embodiment of the present disclosure may include:

The design client of the management platform can detect requirements of the design layer, acquire preset design data from the cloud database, and feed the preset design data back to the design client, so that the design layer can communicate with the design client through an existing application interface to acquire the preset design data. Then, the design layer can perform design, such as modeling design and index design, based on the preset design data to obtain design data corresponding to each building project. The design client communicates with the design layer through an interface of the design layer, so as to acquire the design data uploaded by the design layer. The management platform can forward the design data to the technique and construction method database.

The production client of the management platform can detect requirements of the production layer, acquire preset product data from the cloud database, and feed the preset product data back to the production client, so that the production layer can communicate with the production client through an existing application interface to acquire the preset product data. Then, the production layer can produce based on the preset product data to obtain product data corresponding to each building project. The production client communicates with the production layer through an interface of the production layer, so as to acquire the product data uploaded by the production layer. The management platform can forward the product data to the technique and construction method database.

The construction client of the management platform can detect requirements of the construction layer, acquire a part of design data and product data (such as information about design drawings, supply lists, purchase orders, and logistics transportation) from the technique and construction method database, and feed these data back to the construction client, so that the construction layer can communicate with the construction client through an existing application interface to acquire the design data and the product data. Then, the construction layer can construct based on the design data and the product data to obtain physical operation data corresponding to each building project, i.e., construction data. The construction client communicates with the construction layer through an interface of the construction layer, so as to acquire the construction data uploaded by the construction layer. The management platform can forward the construction data to the technique and construction method database. In practical applications, the construction data can be acquired with reference to the following methods: deploying cameras at fixed points of a building project, capturing construction data of the building project through the cameras, and uploading the construction data to the management platform; or deploying aerial photography devices, capturing construction data of a building project through the aerial photography devices, and uploading the construction data to the management platform. Those data can be stored in the cloud database. The management platform can build a model for the construction data to obtain a 3D model, and then send the 3D model to the technique and construction method database.

The management platform, after acquiring the design data and the product data, can compare the design data with the product data to generate the first comparison data, and store the first comparison data in the cloud database. The first comparison data can be used as a supervision basis for the supervision client to supervise the design layer and the production layer in the management platform.

The management platform, after acquiring the product data and the physical operation data, can compare the product data with the physical operation data to generate the second comparison data, and store the second comparison data in the cloud database. The second comparison data can be used as a supervision basis for the supervision client to supervise the construction layer and the production layer in the management platform.

The visualization platform can read the design data and the construction data from the technique and construction method database for processing to generate and display a three-dimensional model. The three-dimensional model may include a sand table model, which may be displayed on a large-size spliced display screen or a seating desktop computer to embody effects of a building project in different scenes, such as a landscape effect of a community in spring, summer, autumn or winter. The three-dimensional model may include a twin digital model, and the effects of the building project during design, construction, use, etc., can be embodied through the twin digital model. In addition, the visualization platform can realize functions such as electronic signature and distribution supervision, which improves management efficiency.

The management platform can send the first comparison data or the second comparison data to the supervision client, so that the supervision client can generate the supervision instructions according to the first comparison data or the second comparison data, and send the supervision instructions to the design client, the production client, or the construction client to supervise different parties to operate according to requirements, which can achieve effects of check on construction, modification on failure, and real-time visibility.

Alternatively, during the display of the three-dimensional model by the visualization platform, the visualization platform can generate warning information in response to operations of the supervision layer, and send the warning information to the supervision client. The supervision client generates the supervision instructions according to the warning information, and sends the supervision instructions to the design client, the production client or the construction client to supervise different parties to operate according to requirements. It can be seen that providing the warning information through the visualization platform can make data capturing, processing, visualization and supervision form a closed data loop, so as to achieve an effect of improving supervision efficiency.

So far, in this embodiment, by generating the three-dimensional model according to the design data and the construction data and displaying the three-dimensional model, various building projects can be visualized, so as to achieve an effect of real-time supervision. In addition, in the present disclosure, the building project can be simulated by generating the three-dimensional model, so as to learn a full life cycle of the building project, which is beneficial to manage the full life cycle; and the construction progress of the building project can be supervised, so as to achieve an effect that the building project satisfies design requirements.

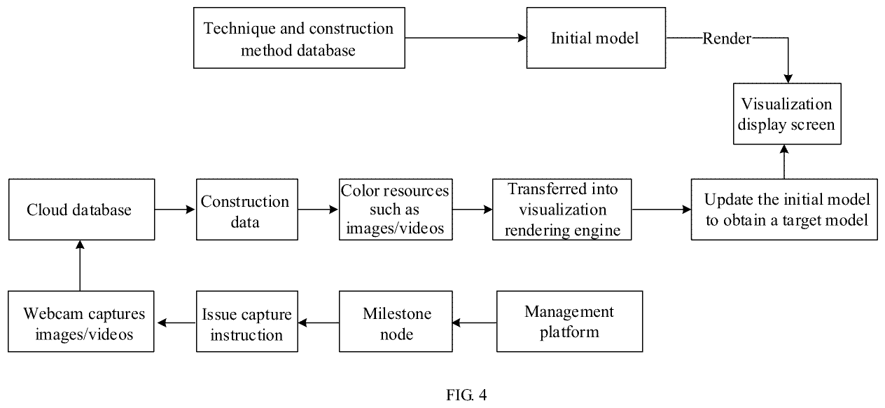

Continuing to refer to FIG. 4, a visualization implementation process of a BIM visualization system provided by an embodiment of the present disclosure may include:

The visualization platform can provide an interactive interface, through which the technique and construction method database can be accessed. During the access, the visualization platform can enumerate models in the technique and construction method database in a list for a user to select.

The visualization platform, in response to a trigger operation by a user on an interactive operation page, can acquire a model corresponding to the trigger operation. Based on the above principle, a three-dimensional model can be formed after multiple operations. Since models provided in the technique and construction method database are ideal models, the three-dimensional model is an initial model, such as a model represented in black and white. Then, the visualization platform renders and displays the initial model on a display screen of the visualization platform.

The management platform can determine milestone nodes according to the design data or the construction data, such as completion of foundation pouring and building capping in a building project. Then, the management platform can determine target locations where images are captured according to the nodes, direct the construction layer to deploy sensors, such as webcams, cameras, or aerial photography devices, at the target locations, and control the sensors to capture the image data. These image data can be uploaded to the cloud database as a part of the construction data.

The visualization platform can continue to access the cloud database of the management platform through the interactive interface to acquire image data corresponding to the milestone nodes and color resource data in images or videos provided by the image data, then transfer the color resource data into a visualization rendering engine, and update the initial model to finally obtain a colored first target model, the effect of which is shown in FIG. 5.

During visualization display, the visualization platform can add a waterwave simulation effect to the three-dimensional model. An implementation process of adding the waterwave simulation effect may include:

In the embodiments, the visualization platform may acquire a first target model. In practical applications, the visualization platform may be equipped with an interactive graphics program, such as OpenSceneGraph (OSG) engine, and during working of the OSG engine, the visualization platform may create an air vehicle, a game, virtual reality, an architectural model, or other 3D model according to user operations. Moreover, some regions of the 3D model involve waters, such as rivers, lakes, oceans, ports, or fountains.

In the embodiments, during simulation, the visualization platform may display an interactive interface, and the interactive interface may include a menu bar, which includes slots in various waterwave formats. A user may select one of the slots from the menu bar as a slot corresponding to a target region of the first target model with reference to actual requirements of the first target model and/or user needs. It should be noted that the first target model may include multiple target regions, and each target region corresponds to one slot. Considering that methods for processing the slots are same, in subsequent embodiments, solutions will be described by taking an example of attaching a slot to a target region, so as to facilitate description and understanding.

In the embodiments, the visualization platform may acquire one or more target regions corresponding to waterwaves in response to detecting that the waterwaves need to be acquired. In practical applications, there are one or more “hollowed” regions in the first target model, and some bitmap images need to be inserted into the one or more “hollowed” regions respectively to obtain a desired effect. In the embodiments, the one or more “hollowed” regions may be used as the one or more target regions corresponding to the waterwaves.

In the embodiments, the visualization platform may be provided with a local database, and the database may store bitmap images, including, but not limited to, bitmaps in a format of jpg, png, bitmap, etc. The database may store pixel matrices parsed from the bitmap images or, related data of the bitmap images, for example, dynamic link library dll files or static link library lib files. When the visualization platform reads nodes involving waters in the first target model, the visualization platform may read the bitmap images from the local database. In this case, the visualization platform may determine that waterwaves need to be acquired during simulation on the first target model. The visualization platform may read the bitmap images from the local database, and insert one or more bitmap images corresponding to one or more target regions into the one or more target regions.

It should be noted that, in the embodiments, before a bitmap image is inserted, the visualization platform may determine whether changes in specified parameters of the first target model are legal, for example, whether a normal angle is between 0 and 180 degrees, or whether a sine value is between 0 and 1 or whether ranges of waterwaves extend to a boundary of the bitmap image. The specified parameters are selected according to particular scenes, which is not limited here.

In the embodiments, the visualization platform may be provided with a local database, and the database may store bitmap images, including, but not limited to, bitmaps in a format of jpg, png, bitmap, etc. The database may store pixel matrices parsed from the bitmap images or, related data of the bitmap images, for example, dynamic link library dll files or static link library lib files. When the visualization platform reads nodes involving waters in the first target model or a user selects a slot for a target region, the visualization platform may read the bitmap images from the local database. In this case, the visualization platform may determine that waterwaves need to be acquired during simulation on the first target model. The visualization platform may acquire one or more slots corresponding to one or more target regions.

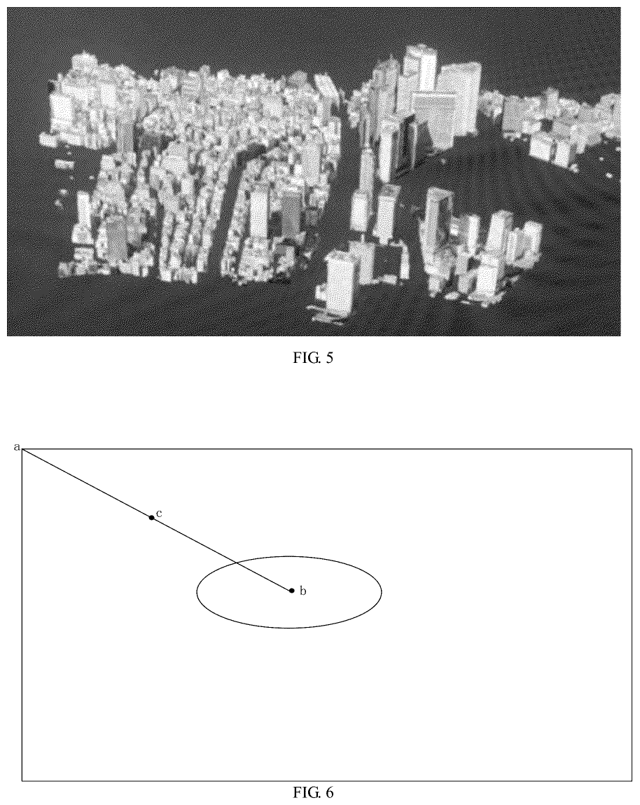

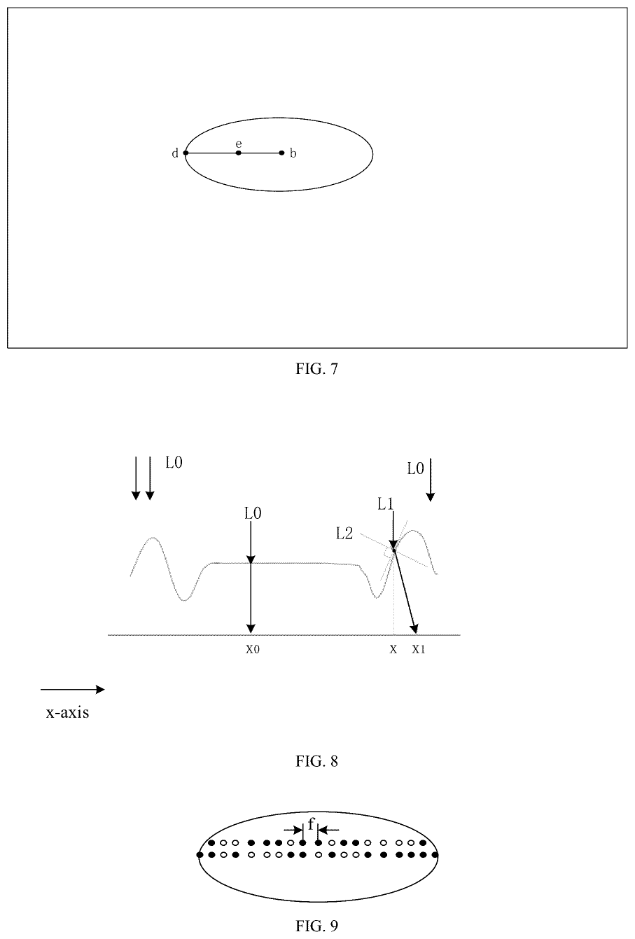

For each of the one or more bitmap images, the visualization platform may acquire a target point in the bitmap image and a normal corresponding to the target point. The target point may be understood as a reference point for processing the bitmap image. The visualization platform may acquire a mapping point and a center point of the bitmap image, where the mapping point indicates a corresponding start point obtained by mapping a coordinate origin of a bitmap image coordinate system to a world coordinate system. The visualization platform may acquire a midpoint of a line between the mapping point and the center point to obtain a first midpoint. In response to detecting that the first midpoint is located within the bitmap image, the visualization platform may determine the first midpoint as the target point. In response to detecting that the first midpoint is located outside the bitmap image, for example, as shown in FIG. 6, midpoint c of a line between mapping point a and center point b of the bitmap image, i.e., first midpoint c, is located outside the bitmap image, the visualization platform may acquire a midpoint of a line between a preset point (for example, a corner point of the bitmap image whose shape is rectangular) and the center point of the bitmap image to obtain a second midpoint, where the second midpoint falls within the bitmap image, for example, as shown in FIG. 7, midpoint e of a line between preset point d and center point b of the bitmap image, i.e., second midpoint e, is located within the bitmap image. In this case, the visualization platform may determine the second midpoint as the target point. In these steps, the reference point for processing the bitmap image can be acquired by acquiring the target point, so as to ensure that waterwaves are located within the bitmap image and improve processing efficiency.

In the embodiments, the normal of the target point is a straight line passing through the target point and parallel to a z-axis in the bitmap image coordinate system. Referring to FIG. 8, a bottom line represents a background plane; a curve containing two sine waves above the background plane represents a water surface, where the sine waves represent waterwaves; and vertical lines perpendicular to the background plane above the water surface represent lines of sight from a user when viewing the water surface. Taking a target point at x0 as an example, the water surface is a plane, and a normal of the water surface is perpendicular to the background plane. A line of sight L0 is parallel to the normal at x0. The line of sight may pass through the water surface and be perpendicular to the background plane. Taking a target point at x as an example, there is a waterwave on the water surface, and the normal, which now becomes L2, is no longer perpendicular to the background plane, that is, an angle is kept therebetween. The line of sight may arrive at x1 through refraction of the waterwave. Based on the above principle, when the water surface includes multiple waterwaves, by adjusting a direction of lines of sight, lines of sight from a user can be unevenly distributed on the background plane to achieve an effect of viewing waterwaves. Based on the effect shown in FIG. 8, it can be known that the normal of the target point is parallel to the z-axis in the bitmap image coordinate system regardless of whether the target point is at the plane or waterwave of the water surface.

The visualization platform may acquire transformation data of pixels around the target point with the normal corresponding to the target point as reference and in conjunction with a preset angle in noise data, and determine to-be-processed pixels according to the target point. It can be understood that the transformation data refers to data required to adjust pixel values of the pixels around the target point to form waterwaves, and the transformation data is associated with the preset angle and direction vectors, where the direction vectors characterize directions between the to-be-processed pixels and the target point, that is, unit vectors formed when viewing from the target point to the to-be-processed pixels, such as (0, 1), (1, −1), (0, −1), (−1, −1), (−1, 0), (−1, 1), (0, 1) and (1, 1). The preset angle refers to an angle formed by a slot (i.e., bitmap image) coordinate system and a first target model coordinate system (i.e., world coordinate system) when the slot coordinate system is mapped to the first target model coordinate system, where the angle can change with the first target model coordinate system, that is, when a user rotates the model to adjust viewing angles, an insertion angle of the slot, that is, the preset angle, can change synchronously. It can be understood that mapping relationship between the slot coordinate system and the world coordinate system can be preset or extracted from an application for generating the model.

In this step, the visualization platform may determine the to-be-processed pixels according to the target point. The visualization platform may acquire candidate pixels that satisfy a first screening condition in the bitmap image. As shown in FIG. 9, black dots in FIG. 9 represent the candidate pixels that satisfy the first screening condition, and circles represent candidate pixels that do not satisfy the first screening condition. The first screening condition includes at least one of: for pixel values of a candidate pixel, a red pixel value is less than or equal to a red pixel threshold; a green pixel value exceeds a green pixel threshold, and a blue pixel value exceeds a first blue pixel threshold and a second blue pixel threshold, where the second blue pixel threshold is greater than the first blue pixel threshold. In this step, by setting the first screening condition, it can be ensured that water color tends toward blue or green instead of red, which is beneficial to improve a simulation effect.

The visualization platform may determine a spacing distance between two adjacent pixels in the bitmap image according to a size of the bitmap image and a size of a display region of a display screen, for example, distance f as shown in FIG. 9. The first target model or a subsequent target model needs to be displayed in the display region of the display screen, so that the size of the display region will affect the spacing distance between adjacent pixels in the bitmap image. After the size of the display region is determined, a size of a target region can be determined synchronously, and since a resolution of the bitmap image is known, the spacing distance between two adjacent pixels in the bitmap image can be determined. By setting the spacing distance, spacing between two waterwaves can be maintained, which ensures the same effect as waterwaves in real life, and improves viewing experience.

It should be noted that the above description is a solution of determining the spacing distance by using the size of the bitmap image and the size of the display region of the display screen. In practical applications, the spacing distance may be set according to empirical values, for example, the spacing distance is set to 3-5 pixels when there is a light wind blowing, and to 10-15 pixels when there is a strong wind blowing, which can also implement the solutions of the present disclosure.

In response to determining that a second screening condition is not satisfied, the visualization platform may repeatedly execute a step of, with a specified point as a start point, moving the specified point by the spacing distance in different directions in sequence until pixels at corresponding positions are non-candidate pixels or the corresponding positions exceed a boundary of the bitmap image, and determine candidate pixels at the corresponding positions as the to-be-processed pixels, where the second screening condition includes: pixels at corresponding positions are located outside the bitmap image or there is no pixel at the corresponding positions after the specified point is moved by the spacing distance, and the specified point includes the target point or respective first candidate pixels that follow the non-candidate pixels. It can be understood that this part of contents may be an iterative step. That is, first, a target point, which serves as reference, can be understood as a position where a stone falls, for which, referring to FIG. 8, x0 is a target point. Then, candidate pixels spaced apart from the target point by a spacing distance are to-be-processed pixels, for example, a pixel at x on a right side is a to-be-processed pixel, and after the to-be-processed pixels are processed, a first strip of waterwave or a first circle of waterwave (i.e., a crest of a wave) can be acquired. Next, after the target point is moved in different directions by a spacing distance, candidate pixels corresponding to locations of the moved target point are used as to-be-processed pixels, and after the to-be-processed pixels are processed, a second strip of waterwave or a second circle of waterwave can be acquired; and so on in an order of “waterwave-normal-waterwave-normal . . . ” until the target point is moved to or beyond a boundary of the bitmap image.

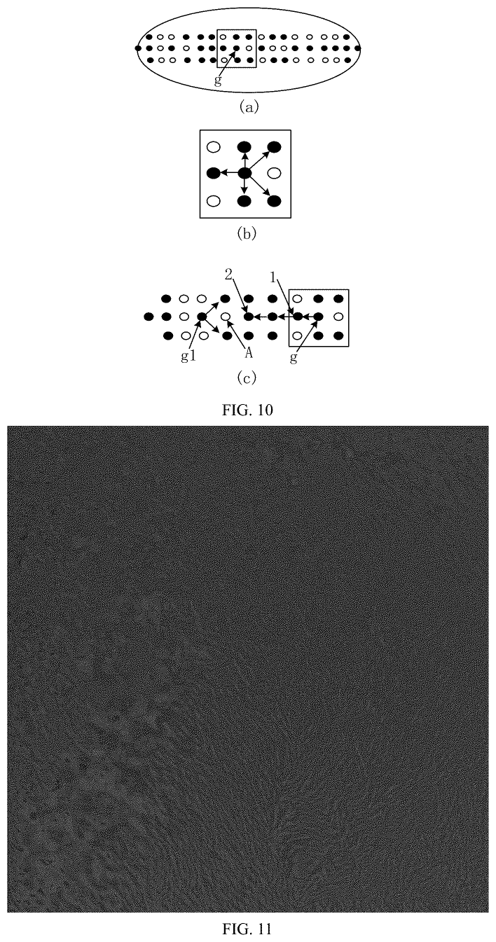

In practical applications, considering that the first time a waterwave is extended in 8 directions of a target point, with reference to FIG. 10, in which, FIG. 10 (a) shows a target point g and FIG. 10 (b) shows that a waterwave is extended in 5 directions that satisfy requirements, for each direction, to-be-processed pixels are adjusted to acquire the waterwave according to the solution in the above embodiment, subsequent extension is continued in the same directions, and if candidate pixels are encountered, pixel brightness will be adjusted to form waterwaves. FIG. 10 (c) shows an effect of moving the target point leftwards three times to form waterwave 1 and waterwave 2. After the target point is moved by the spacing distance, when a corresponding pixel at the location of the moved target point is not candidate pixel (such as pixel A), extension with target point g as reference is stopped. Then, extension in all directions is continued to search for candidate pixels, and each of the found candidate pixels can be used as a specified point to continue extension in 8 directions. For example, as shown in FIG. 10 (c), which shows an effect of finding specified point g1 on a left side, specified point g1 turns into a reference point having the same status as a target point, and subsequent extension based on the specified point is the same as that based on the target point, which will not be repeated here. Based on the principle shown in FIG. 10, search of specified points and extension of waterwaves will be continued until the waterwaves are extended to the boundary or there is no candidate pixel. In this way, waters can be covered with waterwaves through the above extension method.

It should be noted that extending waterwaves in 8 directions with a specified point as reference is suitable for scenes where stones or raindrops fall into waters, and here circles of waterwaves with the specified point as a circle center will be formed. Considering that waters such as lakes or oceans have a larger area and their waterwaves move toward shores, the waterwaves can be extended in four directions from the specified point to the shores, and the same is true for specified points that appear subsequently. In this way, waterwaves that move continuously toward the shores are formed, and the waterwaves match simulation scenes. Person of ordinary skill in the art may select appropriate direction vectors according to particular scenes to ensure flow directions and orientations of waterwaves. The flow directions refer to directions in which the waterwaves move. For example, waterwaves in oceans flow from deep within the oceans to shores. The orientations refer to orientations in which the waterwaves are displayed to a user, that is, angles of waterwaves viewed by the user in different angles of view. For example, a waterwave is viewed from its front, and after a model is rotated by 90 degrees (which can be understood as a change in the preset angle being 90 degrees), a mountain-shaped waterwave with a high middle and two low sides is viewed from its sides.

It should be noted that, considering that a proportion of to-be-processed pixels that satisfy requirements in a bitmap image is nearly half or less than half, that is, less than or equal to 50%, such as 30%, for the whole bitmap image, an average distance between two adjacent specified points is about 2-3 pixels, so that, for each specified point, extension cannot be continued after a first strip of waterwave or a first circle of waterwave is formed, and as a whole, multiple strips of waterwaves or multiple circles of waterwaves can be formed in the whole bitmap image, so that an effect of forming waterwaves in the bitmap image is achieved. That is to say, in the embodiments, with the above-described spacing distance and spacing distances between pixels that do not satisfy requirements combined, final spacing between two adjacent waterwaves can be ensured to achieve a final effect of visually viewing two waterwaves or two waterwaves with large spacing. The visualization platform may determine a transformation matrix corresponding to the bitmap image according to the transformation data and the to-be-processed pixels.

In this step, considering that differences between different waterwaves in the bitmap image lie merely in: changes in direction vectors, or, different orientations of different to-be-processed pixels to a target point, therefore, for different waterwaves, preset angles associated with transformation data for to-be-processed pixels remains unchanged, and direction vectors are changed separately as a variable.

Thus, the visualization platform can determine direction vectors for to-be-processed pixels. With reference to contents exemplified in the above embodiments, the direction vectors are related to a scene where waters are located and a preset angle (such as to which a direction the preset angle points). The scene where waters are located decides that waterwaves are extended in 1, 4 or 8 directions, so that there are direction vectors in 1, 4 or 8 directions for a specified point, and further decides which direction vector is used for to-be-processed pixel in each direction associated with the specified point. The preset angle decides propagation directions of waterwaves, and thereby decides which direction vectors are selected for to-be-processed pixels to use. For example, when a preset angle is 0 degree, a waterwave can be viewed from its front, and in this case, a direction vector pointing to the left or right can be selected for to-be-processed pixels; when a model is rotated by 90 degrees, that is, a change in the preset angle is 90 degrees, a mountain-shaped waterwave can be viewed from its sides, and in this case, a direction vector pointing to or away from a display screen can be selected for to-be-processed pixels. It should be noted that, for the purpose of vivid description, a process of selecting direction vectors is illustrated from perspective of a user viewing the display screen. In practical applications, transformation can be performed according to mapping relationship between a world coordinate system and a bitmap image coordinate system.

Then, the visualization platform may write direction vectors for each to-be-processed pixel and the preset angle into a transformation matrix, and write constant 1 (indicating no need to change) at positions of pixels other than to-be-processed pixels, so as to finally determine a transformation matrix corresponding to the first image.

The visualization platform may obtain the one or more first images by adjusting the one or more bitmap images according to respective transformation matrices. It can be understood that the visualization platform acquires a product of pixels in the first image and transformation data in the transformation matrix according to their corresponding relationships, that is, updates pixel values in to-be-processed pixels in the first image, so as to obtain a second image.

In the embodiments, the transformation matrix can be used to indicate at which positions pixels are adjusted to form waterwaves. Adjusting the pixel values in this step is substantially to adjust brightness values of pixels. High brightness is adopted for pixels at positions of waterwaves, and normal brightness is adopted for pixels at other positions. For pixel values that need to be adjusted in the bitmap image, brightness and contrast adjustments are grayscale linear transformation of the image. Please refer to the following formula:

$$y = [ x - 127.5 * ( 1 - B ) ] * k + 127.5 * ( 1 + B ) ,$$

where x is a pixel value before adjustment, and y is a pixel value after adjustment. B takes a value [−1,1], and is used for adjusting brightness; k is used for adjusting contrast, arctan(k) takes a value [1,89], and k=tan((45+44*c)/180*pi), where c takes a value of preset angle, and usually c is used to set contrast.

In an example, the visualization platform may adjust brightness and contrast of pixels in the following methods:
When B=0, y=(x−127.5)*k+127.5; here only contrast is adjusted.
When c=0, k=1 and y=x+255*B; here only brightness is adjusted.

It should be noted that person of ordinary skill in the art can adjust brightness and contrast of pixels according to the above-described adjustment principle, which will not be repeated here.

In the embodiments, one or more second images are obtained by processing the one or more first images.

In an embodiment, the visualization platform may process the first image to obtain a second image. For example, the visualization platform may perform Fresnel transformation processing on the first image. Fresnel transformation can be understood as Fourier transformation, the purpose of which is to form any continuously measured time sequence or signal and use infinite superposition of sine wave signals with different frequencies. In this way, in this embodiment, waterwaves in an opposite direction (or backwash) appearing when waterwaves are extended in 8 directions based on subsequent reference points can be found through the Fresnel transformation, where the backwash is noise signals with regard to waterwaves generated based on previous reference points, and then sine wave signals with a frequency corresponding to backwash signals are removed to obtain a second image. The solution in this embodiment is suitable for scenes where waters have a larger area and waterwaves flow in the same direction. For example, all waves in oceans flow toward shores. Accuracy of simulation of waterwaves can be ensured through anti-interference processing.

In an embodiment, the visualization platform is provided with noise sources, and the noise sources may generate Monte Carlo random numbers and noise source parameter data, that is, the noise sources first generate the Monte Carlo random numbers, and then input the Monte Carlo random numbers into noise source parameters, thereby generating the noise source parameter data. The noise source parameter data may include different positions and incoming angles of the noise sources, where the noise sources may be equivalent to target points and the incoming angles are equivalent to preset angles, which is suitable for scenes such as waters when it is raining. Waterwaves generated by these noise sources may also interfere with waterwaves generated by the target points. In this embodiment, a sine transformation can be performed on a first image, so that waterwaves respectively corresponding to the target points and the noise sources can be superimposed to obtain a second image, and the second image can be used as a slot corresponding to a target region. In this embodiment, by superimposing noise data, an effect of superimposing different waterwaves can be simulated, and accuracy of waterwaves can be ensured.

In the embodiments, a second target model is obtained by attaching the one or more slots to the first target model, where an effect of waterwaves is present in the one or more target regions of the second target model, as shown in FIG. 11.

It should be noted that, the process of adding the waterwaves to the first target model is completed in an internal memory of the visualization platform, so that in the process of acquiring slots, an internal memory region can be pre-allocated for a bitmap image, and updating pixel values in the bitmap image needs to be performed only on the bitmap image, so that waterwaves will not occupy space in a z-axis direction of the space, and different waterwaves can be formed only by adjusting loading angles; and there is no need to further allocate internal memory space, which can improve internal memory utilization.

In the embodiments, after acquiring the second target model, the visualization platform can exchange the second target model in the internal memory into a display memory, and the display memory can complete rendering for the target model and other display tasks, which will not be described here. It can be understood that, for the display memory, no rendering parameters are added to the second image and the bitmap image, and therefore, using the above method in parts of the second target model where waters are needed is beneficial to improve a simulation effect.

In the technical solutions provided by the present disclosure, in response to detecting that waterwaves need to be acquired during simulation on a first target model, one or more target regions corresponding to the waterwaves, and one or more slots corresponding to the one or more target regions can be acquired; and then the one or more slots are attached to the first target model to obtain a target model, where an effect of waterwaves is present in one or more target regions of the target model. In this way, in the embodiments, the target model can involve waterwaves by attaching the one or more slots with waterwaves to the first target model, and it is only necessary to allocate an internal memory and a display memory for one or more slots without adding extra internal memory and display memory, which is beneficial to improve a simulation efficiency.

An implementation process of adding the waterwaves to the first target model will be described below.

A waterwave simulation SDK is stored in the visualization platform, and the SDK can be called to run during simulation. The visualization platform can retrieve a basic texture local database and an interference parameter database from a local database through dynamic link library or static link library interfaces. The local database and the interference parameter database can be disposed within the technique and construction method database. The basic texture database includes the bitmap images, and the interference parameter database includes the noise data. In practical applications, the steps shown in FIG. 1 can be integrated into a module, which provides only interfaces and static resource packages (for example, prefabricated basic texture images, or parameters such as heights and depths of waves, which can be set).

A user can select, from an interactive interface, one or more slots to be used for one or more target regions of the first target model. The visualization platform, after detecting the one or more slots selected by the user, can acquire basic texture data and interference parameter data corresponding to the one or more slots. Then, the visualization platform can call a breadth calculation model, a refraction calculation model and a normal offset calculation model through data logic layers to process the basic texture data and the interference parameter data. For example, the breadth calculation model can acquire respective start points and respective end points of one or more hollowed regions (or one or more target regions) in the first target model, and then determine a range of the one or more target regions in a display region. The refraction calculation model can acquire an angle at which one or more prefabricated basic texture images (i.e., one or more bitmap image) are placed in a 3D world, that is, a preset angle, and acquire an incoming angle of light or wind at scenes such as waters to determine flow directions and orientations of waterwaves. The normal offset calculation model can acquire coordinates of candidate pixels in the one or more basic texture images that satisfy requirements for pixels/RGB values (i.e., first screening condition), and acquire coordinates of specified points and their normals. It can be understood that when the preset angle does not change and the incoming angle of light or wind changes (that is, noise data changes), changes in normals at target points or specified points in the bitmap image can be caused, and changes in waterwaves can be further caused. Afterwards, the visualization platform can acquire one or more slots after processing one or more basic texture images. Then, a target model can be obtained after the one or more slots are attached to the first target model. Finally, the target model can be displayed on an external preview interface.

It should be noted that the above contents describe a solution of inserting one or more slots into an OSG engine from an angle. In practical applications, the visualization platform can load one or more slots directly at any position in the OSG engine, and here the loading angle can be adjusted (that is, when lines of sight remain unchanged, a preset angle can be adjusted by adjusting a direction to which a normal points) to form corresponding waterwaves in one or more target regions. Moreover, the loading angle will change with the change in spatial angel of a target model, so that flow directions and orientations of displayed waterwaves will change therewith, which achieves an effect of viewing waterwaves in different flow directions and orientations from different angles of view.

Other embodiments of the present disclosure will be readily apparent to those skilled in the art after considering the specification and practicing the contents disclosed herein. The present disclosure is intended to cover any variations, uses, or adaptations of the present disclosure, which follow the general principle of the present disclosure and include common knowledge or conventional technical means in the art that are not disclosed in the present disclosure. The specification and examples are to be regarded as illustrative only. The true scope and spirit of the present disclosure are pointed out by the following claims.

It is to be understood that the present disclosure is not limited to the precise structures that have described and shown in the drawings, and various modifications and changes can be made without departing from the scope thereof. The scope of the disclosure is to be limited only by the appended claims.

1. A BIM visualization system, comprising: a visualization platform and a management platform, wherein the management platform comprises a design client and a construction client;
the management platform is configured to acquire design data uploaded by the design client and construction data uploaded by the construction client, and is further configured to forward the design data to the construction client; and
the visualization platform is configured to acquire the design data and the construction data from the management platform, generate a three-dimensional model according to the design data and the construction data, and display the three-dimensional model.

2. The system according to claim 1, wherein the management platform further comprises a supervision client, and
the management platform is further configured to generate supervision data by the supervision client and forward the supervision data to the design client and the construction client.

3. The system according to claim 2, wherein the supervision client is configured to acquire preset design data and the design data forwarded by the management platform, and compare the design data with the preset design data to generate design supervision data.

4. The system according to claim 3, wherein the supervision client is configured to acquire preset product data and product data forwarded by the management platform, and compare the preset product data with the product data to generate production supervision data, where the production supervision data is used to characterize whether products satisfy requirements of the preset product data.

5. The system according to claim 4, wherein the supervision client is configured to acquire the preset design data and the construction data forwarded by the management platform, and compare the preset design data with the construction data to generate construction supervision data, where the construction supervision data is used to characterize whether the products are subjected to construction operation according to the requirements of the preset design data.

6. The system according to claim 1, wherein the management platform is configured to compare the design data with product data forwarded by the management platform to generate first comparison data, where the first comparison data is used to characterize whether products satisfy requirements of the design data.

7. The system according to claim 1, wherein the management platform is configured to compare product data forwarded by the management platform with the construction data to generate second comparison data, where the second comparison data is used to characterize whether physical products satisfy requirements of the product data.

8. The system according to claim 1, further comprising: a technique and construction method database, wherein the technique and construction method database communicates with the management platform; and
the management platform is configured to acquire the design data form the technique and construction method database, and forward the design data to the design client, the construction client, or a supervision client in the management platform.

9. The system according to claim 1, wherein the management platform comprises: a cloud database configured to store preset design data and preset product data.

10. The system according to claim 1, wherein the management platform further comprises a production client, and the management platform is further configured to acquire preset product data and product data uploaded by the production client.
